(19) United States
(12) Patent Application Publication
(10) Pub. No.: US 2026/0165110 A1
(43) Pub. Date: Jun. 11, 2026

(54) MULTI-LAYER PAD STRUCTURE FOR A SEMICONDUCTOR DEVICE

(71) Applicant: Micron Technology, Inc., Boise, ID (US)

(72) Inventors: Che-Chi LEE, Boise, ID (US); Soichi SUGIURA, Boise, ID (US); Vinay NAIR, Boise, ID (US); Protyush SAHU, Boise, ID (US); Russell A. BENSON, Boise, ID (US); Silvia BORSARI, Boise, ID (US)

(21) Appl. No.: 19/183,261

(22) Filed: Apr. 18, 2025

Related U.S. Application Data
(60) Provisional application No. 63/653,482, filed on May 30, 2024.

(51) Int. Cl. H10W 20/41; H10B 12/00; H10D 62/83; H10D 62/85; H10W 20/00; H10W 20/44

(52) U.S. Cl. CPC H10W 20/435; H10B 12/0335; H10D 62/83; H10D 62/85; H10D 62/8503; H10W 20/057; H10W 20/062; H10W 20/064; H10W 20/4405; H10W 20/4441; H10B 12/485

(57) ABSTRACT

Implementations described herein relate to various structures, integrated assemblies, and memory devices. In some implementations, an integrated assembly includes a semiconductor device structure. The semiconductor device structure includes a first semiconductive layer and a multi-layer pad structure over the first semiconductive layer that extending laterally beyond the first semiconductive layer. The multi-layer pad structure includes a second semiconductive layer having at least a portion that is directly on and conjoined with the first semiconductive layer, and compound layer that is directly on and conjoined with the second semiconductive layer and a conductive layer stack that is directly on and conjoined with the compound layer.

### CROSS-REFERENCE TO RELATED APPLICATION

This Patent Application claims priority to U.S. Provisional Patent Application No. 63/653,482, filed on May 30, 2024, entitled “MULTI-LAYER PAD STRUCTURE FOR A SEMICONDUCTOR DEVICE,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a multi-layer pad structure for a semiconductor device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell.

FIG. 2 includes a diagrammatic view of an example implementation described herein.

FIG. 3 is a flowchart of an example method of forming an integrated assembly or memory device having a multi-layer pad structure described herein.

FIGS. 4A through 4J are diagrammatic views showing formation of portions of a semiconductor device including the multi-layer pad structure at example process stages of an example process of forming the semiconductor device including the multi-layer pad structure.

FIG. 5 is a diagrammatic view of an example memory device described herein.

### DETAILED DESCRIPTION

In the semiconductor manufacturing industry, significant challenges stem from the continuous drive toward miniaturization and scaling. As an example, manufacturing cell contact (CC) pad structures for memory cells presents considerable difficulties due to a shrinking contact landing area and high aspect ratio, deep-trench contacts required for forming the cell contact structures. As semiconductor manufacturing process nodes (e.g., semiconductor manufacturing dimensional capabilities) scale down, it becomes increasingly problematic to maintain the contact landing area within a controlled resistive range, resulting in escalating concerns regarding the cell contact pad structure's performance and reliability.

Some implementations described herein provide a method for manufacturing cell contact pad structures for memory cells that enhances manufacturing efficiency and increases performance (e.g., reduces contact resistance) of the cell contact pad structures through improvements in materials and processes.

In some implementations, and as an example, a semiconductor device structure includes a cell contact pad structure that is a multi-layer pad structure. The multi-layer pad structure may include an epitaxial layer that is conjoined directly with a polysilicon layer, a silicide layer that is conjoined directly with the epitaxial layer, and a metallization stack that is conjoined directly with the silicide layer.

In contrast to other cell contact pad structures, the multi-layer pad structure may enable an increase in a width of the cell contact pad structure to reduce contact resistance. Furthermore, the multi-layer pad structure may have a reduced thickness to reduce a likelihood of voids and/or defects that may otherwise be incurred through high-aspect ratio (HAR) etching manufacturing processes and/or annealing manufacturing processes.

In this way, quality and/or reliability of the semiconductor device is improved. By improving the quality and/or the reliability of the semiconductor device, an amount of resources used to support a market consuming the semiconductor device (e.g., raw materials, semiconductor manufacturing tools, labor, and/or computing resources) is reduced.

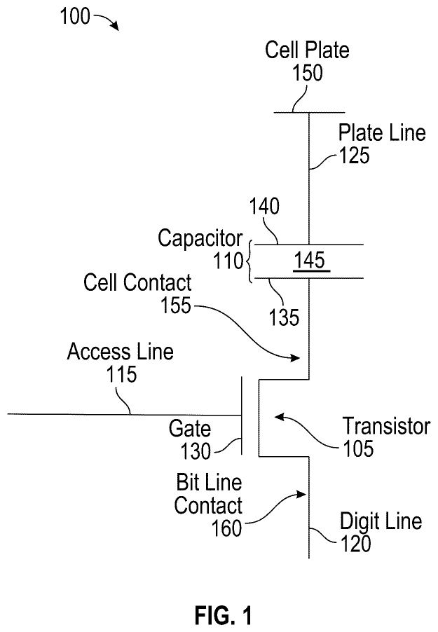

FIG. 1 is a circuit diagram of an example memory cell 100. In some implementations, the memory cell 100 is a ferroelectric memory cell. Alternatively, the memory cell 100 may be a linear dielectric memory cell or a paraelectric memory cell. As shown in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a bit line 120 (sometimes called a “digit line”), and a plate line 125.

The transistor 105 (sometimes called an access transistor) may include a gate 130. The capacitor 110 includes a bottom electrode 135 and a top electrode 140 separated by an insulator 145. In some implementations, the capacitor is a ferroelectric capacitor, and the insulator 145 is a ferroelectric insulator that comprises, consists of, or consists essentially of ferroelectric material. Alternatively, the capacitor may be a linear dielectric capacitor, and the insulator 145 may be a linear dielectric insulator that comprises, consists of, or consists essentially of linear dielectric material. Alternatively, the capacitor may be a paraelectric capacitor, and the insulator 145 may be a paraelectric insulator that comprises, consists of, or consists essentially of paraelectric material. When the access line 115 is activated (e.g., when a voltage is applied to the access line 115), the gate 130 coupled to the access line 115 may be activated. When the gate 130 is activated, the transistor 105 couples the bit line 120 to the bottom electrode 135 of the capacitor 110. A state of the memory cell 100 may then be written or read via the bit line 120.

The top electrode 140 of the capacitor 110 may be coupled to the plate line 125 and a cell plate 150. To write to (or program) the memory cell 100, the access line 115 may be activated, and a voltage may be applied across the capacitor 110 by controlling the voltage of the top electrode 140 (via the plate line 125 and/or the cell plate 150) and/or the bottom electrode 135 (via the bit line 120).

For a ferroelectric capacitor, the applied voltage creates an electric field, and the atoms in the ferroelectric material of the insulator 145 respond to the electric field to become arranged in a particular state (e.g., a particular orientation or polarization), which is representative of a data state (e.g., a logic “0” state or a logic “1” state). In some implementations, data may be stored using the capacitor 110 by controlling a voltage difference and/or a polarity difference of the capacitor 110 (e.g., of the insulator 145 between the bottom electrode 135 and the top electrode 140). For example, a voltage of the cell plate 150 and the bit line 120 may be controlled. In some implementations, a negative polarity of the insulator 145 as compared to the cell plate 150 results in a logic “0” state being stored in the capacitor 110, and a positive polarity of the insulator 145 as compared to the cell plate 150 results in a logic “1” state being stored in the capacitor 110. For a linear dielectric capacitor or a paraelectric capacitor, the cell plate 150 may grounded, and the capacitor 110 may be charged by applying a voltage to the bottom electrode 135 via the bit line 120.

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The magnitude of the change in stored charge may depend on the stored state of capacitor 110 (e.g., whether the stored state is a logic “1” state or a logic “0” state). This may or may not induce a threshold change in the voltage of the bit line 120 based on the charge stored on the capacitor 110. The change in voltage or lack of change in voltage of the bit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

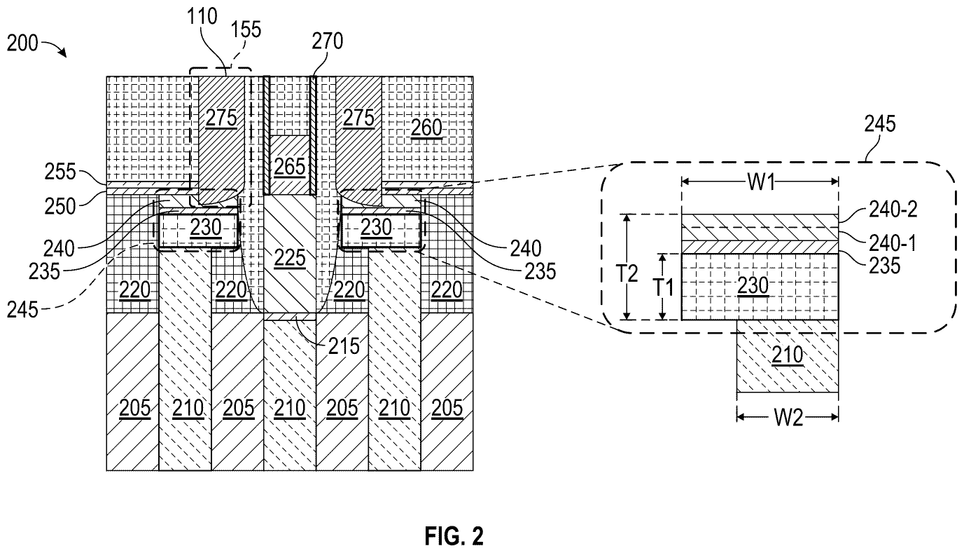

In some implementations, the memory cell 100 is accessed using a cell contact 155 and a bit line contact 160. The cell contact 155 may be part of a connection between the capacitor 110 and the transistor 105, and the bit line contact 160 may be part of a connection between the bit line 120 and the transistor 105. As described in greater detail in connection with FIGS. 2-5, the cell contact 155 may electrically connect with the transistor 105 using a multi-layer pad structure (e.g., a cell contact pad structure) that includes multiple layers and that extends over a shallow trench isolation region of the memory cell 100.

As indicated above, FIG. 1 is provided as an example. Other examples may differ from what is described with respect to FIG. 1.

FIG. 2 includes a diagrammatic view of an example implementation 200 described herein. The implementation 200, which corresponds to one or more portions of a semiconductor device (e.g., the memory cell 100 of FIG. 1), may include one or more features related to a multi-layer pad structure described herein.

Dielectric layer 205, positioned at the base, serves as an insulation layer and may be fabricated from materials such as silicon oxide or silicon nitride and may provide additional electrical insulation necessary for functionality of the semiconductor device. In some implementations, the dielectric layer 205 corresponds to a shallow trench isolation region of the semiconductor device.

Semiconductive layer 210, directly on and conjoined with dielectric layer 205, may be fabricated from materials such as polysilicon, gallium arsenide, indium phosphide, or gallium nitride, providing an active area for the semiconductor device. In some implementations, the semiconductive layer 210 corresponds to source/drain region of a transistor (e.g., a source/drain region of the transistor 105 of FIG. 1)

Conductive layer 215, directly on and conjoined with semiconductive layer 210, functions as an electrically conductive path and may be fabricated from materials like silicide, tungsten, aluminum, or titanium nitride, and provide electrical connectivity with other components of the semiconductor device. In some implementations, the conductive layer 215 corresponds to a gate of a transistor (e.g., the gate 130 of FIG. 1).

Above conductive layer 215, dielectric layer 220 acts as an additional insulation layer, similar to dielectric layer 205 in terms of material properties. The dielectric layer 220 may be fabricated from materials such as silicon oxide or silicon nitride, and provide additional electrical insulation necessary for functionality of the semiconductor device. Further, the dielectric layer 220 is conjoined with a conductive layer 225. The conductive layer 225, which may represent a metallization layer, may be fabricated from materials such as tungsten, aluminum, or titanium nitride and provide electrical connectivity with other components of the semiconductor device. In some implementations, the conductive layer 225 corresponds to a bit line contact structure (e.g., the bit line contact 165 of FIG. 1).

This is followed by a semiconductive layer 230 that is directly on and conjoined with dielectric layer 220. The semiconductive layer 230, which may represent an epitaxial layer, may be fabricated from materials such as polysilicon, gallium arsenide, gallium nitride, indium phosphide, or silicon germanium, and provide semiconductive connections with other components of the semiconductor device. At least a portion of the semiconductive layer 230 may extend laterally beyond the semiconductive layer 210.

In some implementations, the semiconductive layer 230 and the semiconductive layer 210 share a same material (e.g., same semiconductive material). In some implementations, the semiconductive layer 230 and the semiconductive layer 210 have different materials (e.g., different semiconductive materials).

As shown further shown in FIG. 2, a compound layer 235 is directly on and conjoined with the semiconductive layer 230. The compound layer 235 may include a metal element that is combined with a base material of the semiconductive layer 210 (e.g., polysilicon), and include cobalt silicide, titanium silicide, or nickel silicide to introduce low electrical resistance and/or increase adhesive properties with other components.

Conductive layer(s) 240, which may represent a conductive layer stack or a metallization stack, are positioned directly on and conjoined with compound layer 235. The conductive layer(s) 240 may be fabricated from materials such as tungsten, aluminum, or titanium nitride, and provide electrical connectivity with other components of the semiconductor device. In some implementations, the conductive layer(s) 240 include a single conductive layer. Alternatively, and in some implementations, the conductive layer(s) 240 include two or more conductive layers.

As shown in the magnified view in the right hand side of FIG. 2, the semiconductive layer 230, the compound layer 235, and the conductive layer(s) 240 (shown as the conductive layer 240-1 that is a lower layer and the conductive layer 240-2 that is an upper layer) may combine to form a multi-layer pad structure 245 (e.g., a cell contact pad structure).

The multi-layer pad structure 245 may have a combination of one or more dimensional properties that improve a performance of the semiconductor device. For example, the multi-layer pad structure 245 may have a width W1 that is greater than a width W2 of the underlying semiconductive layer 210, providing an increased landing area for a reduced contact resistance with another component (e.g., a cell contact structure).

Additionally, or alternatively, the multi-layer pad structure 245 may have a combination of one or more dimensional properties that are indicative of a semiconductor manufacturing process implemented to improve a quality and/or a reliability of the semiconductor device. For example, a thickness T1 of the semiconductive layer 230 (e.g., an epitaxial layer) may be less than approximately 20 nanometers. Additionally, or alternatively, a ratio of the width W1 of the multi-layer pad structure 245 (e.g., a cell contact pad) to a thickness T2 of the multi-layer pad structure 245 (e.g., W1:T2) may be less than approximately 3:2. A thickness T1 that is greater than approximately 20 nanometers, and/or a ratio W1:T2 that is greater than approximately 3:2, may be indicative of a semiconductor manufacturing process that uses extraneous operations that include high aspect ratio (HAR) depositions and etches, thereby leading to an increased likelihood of voids and/or defects in the multi-layer pad structure 245. In contrast, a thickness T1 that is less than or equal to approximately 20 nanometers, and/or a ratio W1:T2 that is less than or equal to approximately 3:2, may be indicative of a semiconductor manufacturing process that uses a reduced number of operations, thereby leading to a reduced likelihood of voids and/or defects in the multi-layer pad structure 245.

As further shown in FIG. 2, dielectric layers 250 and 255 are sequentially positioned above conductive layer(s) 240. The dielectric layers 250 and 255 may be fabricated from materials such as silicon oxide or silicon nitride and provide additional electrical insulation necessary for functionality of the semiconductor device.

One or more dielectric layers 260 may be over and/or on the dielectric layer 250. The dielectric layers 260 may be fabricated from materials such as silicon oxide or silicon nitride and provide additional electrical insulation necessary for functionality of the semiconductor device.

An additional conductive layer 265 is directly on and conjoined with the conductive layer 225. The conductive layer 265 may be fabricated from materials such as tungsten, aluminum, or titanium nitride, and provide electrical connectivity with other components of the semiconductor device. In some implementations, the conductive layer 265 corresponds to a bit line structure (e.g., the bit line 120 of FIG. 1).

Dielectric layer 270, followed by conductive layer 275, continues the pattern of alternating insulative and conductive materials, ensuring both structural integrity and electrical function within the semiconductor device. The dielectric layer 270 may be fabricated from materials such as silicon oxide or silicon nitride and provide additional electrical insulation necessary for functionality of the semiconductor device. The conductive layer 275 may be fabricated from materials such as tungsten, aluminum, or titanium nitride, and provide electrical connectivity with other components of the semiconductor device. In some implementations, the conductive layer 275 corresponds to a cell contact structure (e.g., the cell contact 155 of FIG. 1) that is directly on and conjoined with the multi-layer pad structure 245. Additionally, or alternatively, the conductive layer 275 may electrically couple with a capacitive structure (e.g., the capacitor 110 of FIG. 1).

As indicated above, FIG. 2 is provided as an example. Other examples may differ from what is described with regard to FIG. 2.

As described in connection with FIG. 1 and FIG. 2, and in some implementations, an integrated assembly (e.g., the memory cell 100) includes a semiconductor device structure. The semiconductor device structure includes a first semiconductive layer (e.g., the semiconductive layer 210) and a multi-layer pad structure (e.g., the multi-layer pad structure 245) over the first semiconductive layer that extends laterally beyond the first semiconductive layer. The multi-layer pad structure includes a second semiconductive layer (e.g., the semiconductive layer 230) having at least a portion that is directly on and conjoined with the first semiconductive layer, and a compound layer (e.g., the compound layer 235) that is directly on and conjoined with the second semiconductive layer and that includes a base material of the second semiconductive layer combined with a metal element. The multi-layer pad structure further includes a conductive layer stack (e.g., the conductive layer(s) 240) that is directly on and conjoined with the compound layer.

Additionally, or alternatively and in some implementations, an apparatus (e.g., the memory cell 100) includes a capacitive structure (e.g., the capacitor 110), a cell contact structure that includes a single conductive layer (e.g., the conductive layer 275) and that is electrically coupled with the capacitive structure, an active area (e.g., the semiconductive layer 210), a shallow trench isolation region (e.g., the dielectric layer that 205) that is proximate to the active area, and a cell contact pad structure (e.g., the multi-layer pad structure 245) that is between the cell contact structure and the active area and that overlaps at least a portion of the shallow trench isolation region. The cell contact pad structure includes a semiconductive layer (e.g., the semiconductive layer 230) having at least a portion directly on and conjoined with the active area, a silicide layer (e.g., the compound layer 235) having at least a portion directly on and conjoined with the semiconductive layer, and a metallization stack (e.g., the conductive layer(s) 240) directly on and conjoined with the silicide layer.

The implementations may improve a quality and/or a reliability of a semiconductor device by reducing contact resistance (e.g., cell contact resistance between a cell contact and a cell contact pad) and/or reducing a likelihood of voids within the semiconductor device (e.g., voids within the cell contact pad). By improving the quality and/or the reliability, an amount of resources used to support a market consuming the semiconductor device (e.g., raw materials, semiconductor manufacturing tools, labor, and/or computing resources) is reduced.

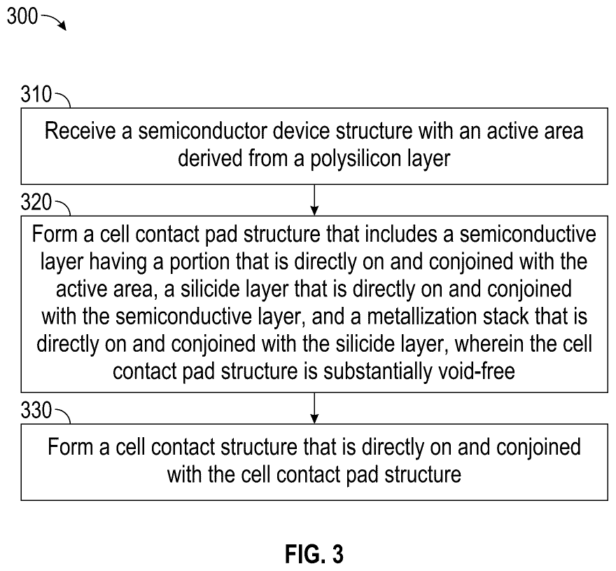

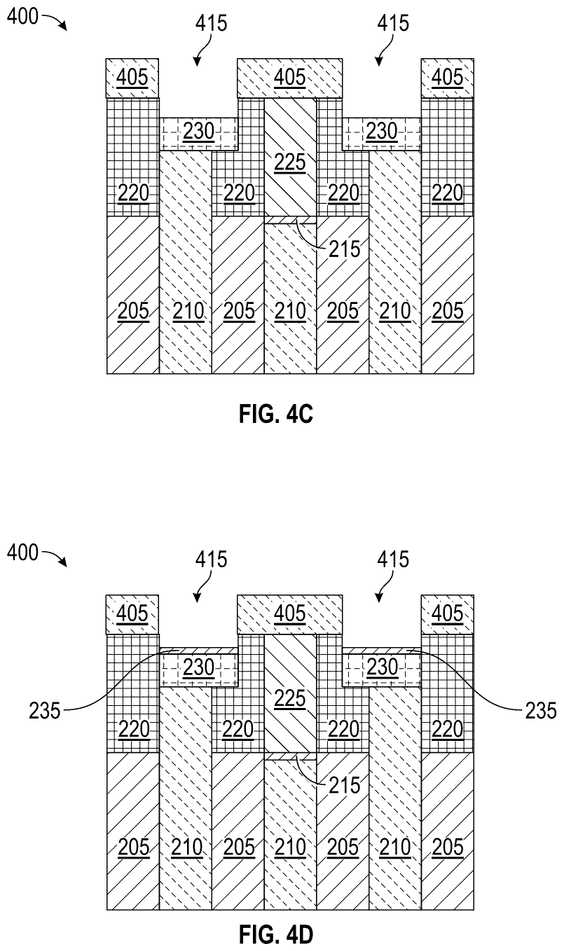

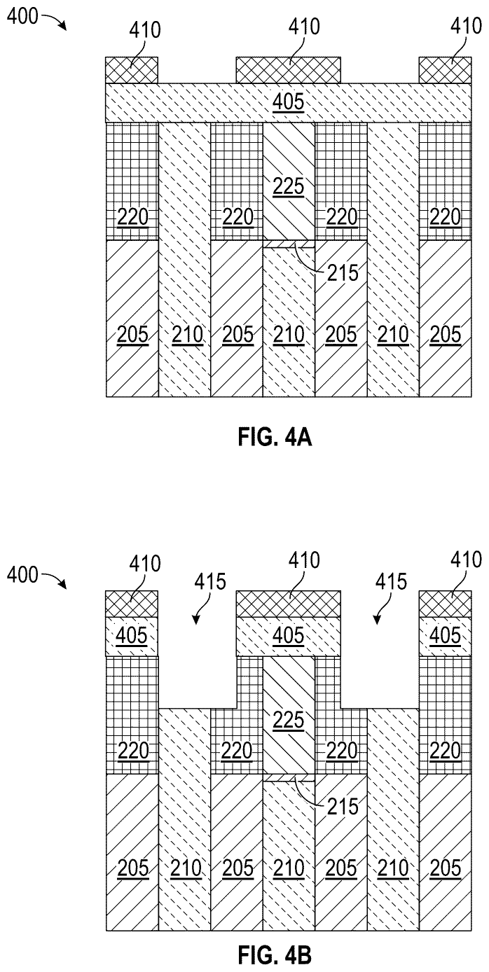

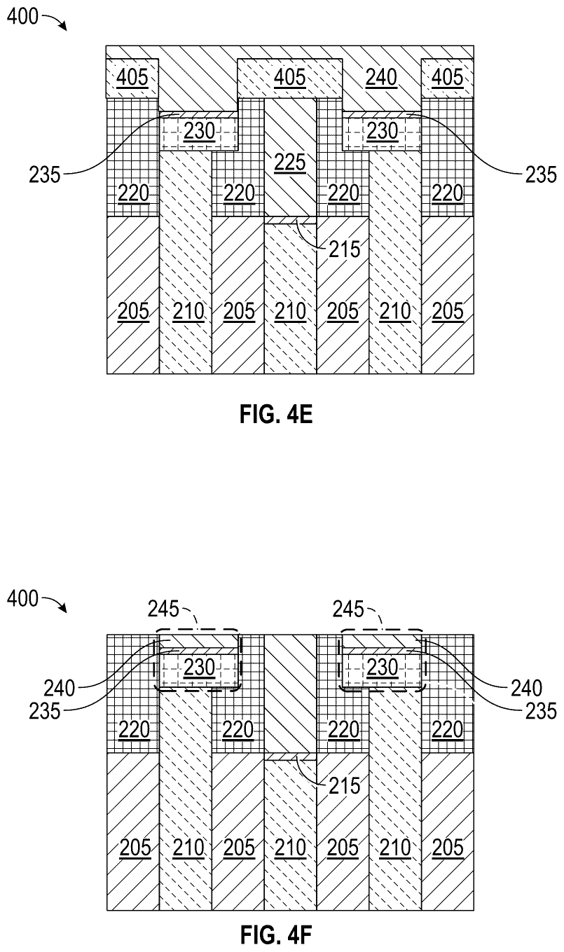

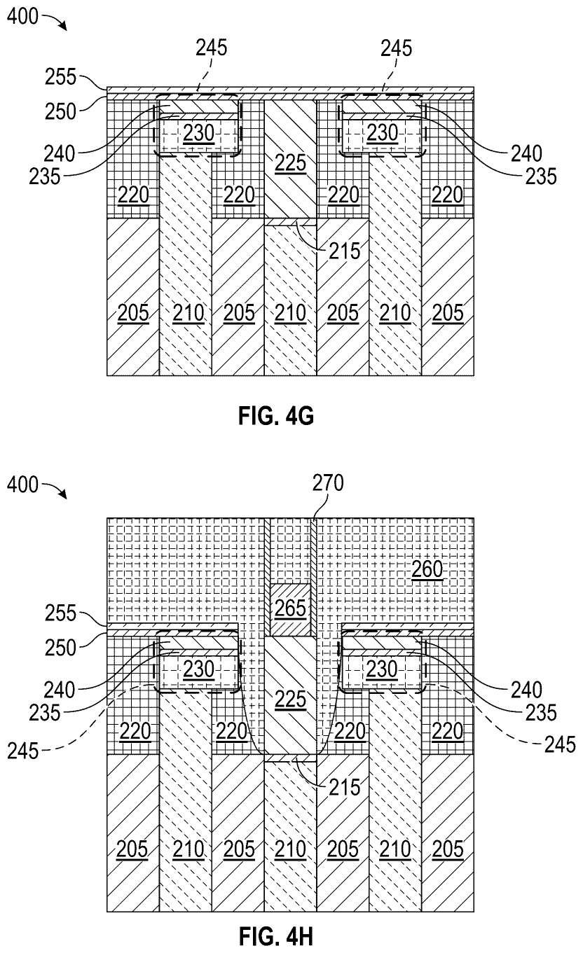

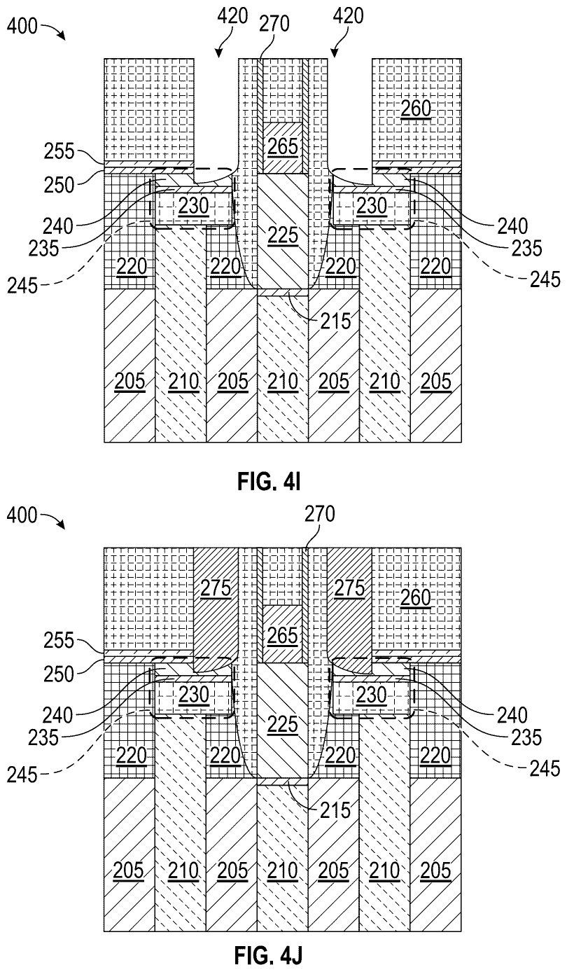

FIG. 3 is a flowchart of an example method 300 of forming an integrated assembly or memory device having a multi-layer pad structure (e.g., the multi-layer pad structure 245) described herein. In some implementations, and as described in greater detail in connection with FIGS. 4A-4J, one or more process blocks of FIG. 3 may be performed by various semiconductor manufacturing equipment.

As shown in FIG. 3, the method 300 may include receiving a semiconductor device structure with an active area (e.g., the semiconductive layer 210) derived from a polysilicon layer (block 310). As further shown in FIG. 3, the method 300 may include forming a cell contact pad structure (e.g., the multi-layer pad structure 245) that includes a semiconductive layer (e.g., the semiconductive layer 230) having a portion that is directly on and conjoined with the active area, a silicide layer (e.g., the compound layer 235) that is directly on and conjoined with the semiconductive layer, and a metallization stack (e.g., the conductive layer(s) 240) that is directly on and conjoined with the silicide layer, wherein the cell contact pad structure is substantially void-free (block 320). As further shown in FIG. 3, the method 300 may include forming a cell contact structure (e.g., the conductive layer 275) that is directly on and conjoined with the cell contact pad structure (block 330).

The method 300 may include additional aspects, such as any single aspect or any combination of aspects described below and/or in connection with one or more other methods described elsewhere herein.

In a first aspect, forming the cell contact pad structure includes forming the semiconductive layer using an epitaxial growth operation.

In a second aspect, alone or in combination with the first aspect, the method 300 includes exposing the semiconductive device structure to an annealing operation, wherein a thermal budget of the silicide layer satisfies a temperature threshold associated with the annealing operation.

In a third aspect, alone or in combination with one or more of the first and second aspects, forming the cell contact pad structure includes forming a cavity that removes portions of the active area and a dielectric layer (e.g., the dielectric layer 220) adjacent to the active area, and forming the cell contact pad structure in the cavity.

In a fourth aspect, alone or in combination with one or more of the first through third aspects, forming the cell contact pad structure includes forming the cell contact pad structure using a hard mask pattern to mask a bit line contact structure during formation of at least a portion of the cell contact pad structure.

In a fifth aspect, alone or in combination with one or more of the first through fourth aspects, forming the cell contact pad structure includes depositing the metallization stack directly on the silicide layer, and planarizing the metallization stack.

In a sixth aspect, alone or in combination with one or more of the first through fifth aspects, forming the cell contact pad structure includes forming the metallization stack from a single metallization layer (e.g., the conductive layer 240-1).

In a seventh aspect, alone or in combination with one or more of the first through sixth aspects, forming the cell contact pad structure includes forming the metallization stack from at least two metallization layers (e.g., the conductive layer 240-1 and the conductive layer 240-2).

In an eighth aspect, alone or in combination with one or more of the first through seventh aspects, forming the cell contact structure includes forming the cell contact structure using a selective deposition process that forms the cell contact structure from a single conductive layer.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the multi-layer pad structure 245, an integrated assembly that includes the multi-layer pad structure 245, any part described herein of the multi-layer pad structure 245, and/or any part described herein of an integrated assembly that includes the multi-layer pad structure 245. For example, the method 300 may include forming the memory cell 100.

FIGS. 4A through 4J are diagrammatic views showing formation of portions of a semiconductor device including the multi-layer pad structure 245 at example process stages of an example process 400 of forming the semiconductor device including the multi-layer pad structure 245. In some implementations, the process 400 described below in connection with FIGS. 4A through 4J may correspond to the method 300 and/or one or more blocks of the method 300. However, the process 400 described below is an example, and other example processes may be used to form the multi-layer pad structure 245, an integrated assembly that includes the multi-layer pad structure 245, and/or one or more parts of the multi-layer pad structure 245 and/or the integrated assembly.

As shown in FIG. 4A, the process 400 may include forming a photoresist layer 410 that is patterned over a dielectric layer 405 (e.g., a hard mask layer). The dielectric layer 405 may comprise, consist of, or consist essentially of an oxide, among other examples. A deposition tool may be used to deposit the photoresist layer 410 using a spin coating technique. An exposure tool (e.g., a light source) may be used to transfer a geometric pattern from a photomask to the photoresist layer 410, and a developer tool may be used to remove portions of the photoresist layer 410 to render the geometric pattern.

As shown in FIG. 4B, the process 400 may include forming cavities 415. The formation of cavities 415 may include etching away portions of the dielectric layer 405, portions of the semiconductive layer 210, and portions of the dielectric layer 220. An etch tool may be used to perform an etch operation that introduces cavities 415 through a process such as a plasma-based etch operation, or a gas-based etch operation. The etch operation may include an anisotropic etch operation, which involves removing material at different rates across multiple different directions, or an isotropic etch operation, which removes material at a same rate across multiple, different directions.

As shown in FIG. 4C, the process 400 may include forming semiconductive layer 230 over and/or on the semiconductive layer 210 within cavities 415. The semiconductive layer 230 may comprise, consist of, or consist essentially of materials including polysilicon, gallium arsenide, indium phosphide, or gallium nitride, among other examples. In some implementations, a deposition tool may be used for deposition of the semiconductive layer 230, using epitaxial growth techniques, chemical vapor deposition (CVD) techniques, or physical vapor deposition (PVD) techniques. In some implementations, portions of the semiconductive layer 230 extend over the dielectric layer 220.

As shown in FIG. 4D, the process 400 may include forming the compound layer 235 directly on the semiconductive layer 230 such that the compound layer 235 is directly conjoined with the semiconductive layer 230. The compound layer 235 may comprise, consist of, or consist essentially of a base material of the semiconductive layer 210 combined with a metal element. For example, in a case in which the semiconductive layer includes polysilicon (e.g., a base material), the compound layer 235 may comprise, consist, or consist essentially of a silicide, such as cobalt silicide, titanium silicide, or nickel silicide, among other examples. A deposition tool may be used to form the compound layer 235 using sputtering techniques or CVD techniques.

As shown in FIG. 4E, the process 400 may include forming conductive layer(s) 240 over and or on the compound layer 235 such that a bottom layer of the conductive layer(s) 240 is conjoined with the compound layer 235. The conductive layer(s) 240 may comprise, consist of, or consist essentially of materials such as tungsten, aluminum, and titanium nitride, among other examples. In some implementations, a deposition tool may be used for deposition of the conductive layer(s) 240 using a PVD technique, an atomic layer deposition (ALD) technique, a CVD technique, an electroplating technique, or other suitable deposition technique.

As shown in FIG. 4F, the process 400 may include removing a portion of the conductive layer(s) 240 to form the multi-layer pad structure 245. A planarization tool may be used to remove the portion of the conductive layers(s) 240 using a chemical mechanical planarization technique, among other examples.

This step in the multi-layer pad structure 245 formation utilizes the underlying compound layer 235 to provide a stable foundation. The compound layer 235 may consist of materials such as cobalt silicide, titanium silicide, or nickel silicide. The utilization of a conductive layer stack, including conductive layer 240 over compound layer 235, allows for the creation of a highly conductive path for electron flow, reinforcing the integrated assembly's electrical performance.

Moreover, by layering conductive materials using precision deposition techniques and subsequent planarization, the process seeks to eliminate void formation. This addresses the challenge presented by high aspect ratio, deep-trench contact structures in dynamic random-access memory (DRAM) metal cell contact formation, resulting in a cell contact pad structure that is substantially void-free. The conductive layer stack, including the conductive layer 240 and the compound layer 235, adheres to the stringent requirements for thermal budgets, ensuring that the layer stack can withstand subsequent thermal anneals without degradation.

By integrating the cell contact stack during the cell contact pad (CCPAD) formation stage, implementations provide a streamlined process flow that bypasses the complexities of traditional high aspect ratio depositions and etches within the trenches, offering a practical and efficient solution to DRAM manufacturing challenges.

As shown in FIG. 4G, the process 400 may include forming dielectric layers 250 and 255 over the multi-layer pad structure 245. The dielectric layers 250 and 255 may comprise, consist of, or consist essentially of materials such as an oxide, among other examples. In some implementations, a deposition tool may be used for deposition of the dielectric layers 250 and 255 using a PVD technique, an atomic layer deposition (ALD) technique, a CVD technique, an electroplating technique, or other suitable deposition technique.

As shown in FIG. 4H, the process 400 may include forming additional structures (e.g., one or more portions of a bit line) that include the dielectric layer(s) 260, the conductive layer 265, and the dielectric layer 270. Forming the additional structures may include using an etch tool to form a cavity that penetrates through the dielectric layer 255, the dielectric layer 250, and into the dielectric layer 220. An etch tool may be used to perform an etch operation that introduces the cavity through a process such as a plasma-based etch operation, or a gas-based etch operation. The etch operation may include an anisotropic etch operation, which involves removing material at different rates across multiple different directions, or an isotropic etch operation, which removes material at a same rate across multiple, different directions.

The dielectric layer(s) 260 and/or the dielectric layer 270 of FIG. 4H may comprise, consist of, or consist essentially of materials such as an oxide, among other examples. The conductive layer 265 of FIG. 4H may comprise, consist of, or consist essentially of materials such as tungsten, aluminum, and titanium nitride, among other examples. In some implementations, a deposition tool may be used for deposition of the dielectric layer(s) 260, the conductive layer 265, and/or the dielectric layer 270 using a PVD technique, an atomic layer deposition (ALD) technique, a CVD technique, an electroplating technique, or other suitable deposition technique.

As shown in FIG. 4I, the process 400 may include forming cavities 420. The formation of the cavities 420 may include etching away portions of the dielectric layer(s) 260. An etch tool may be used to perform an etch operation that introduces cavities 420 through a process such as a plasma-based etch operation, or a gas-based etch operation. The etch operation may include an anisotropic etch operation, which involves removing material at different rates across multiple different directions, or an isotropic etch operation, which removes material at a same rate across multiple, different directions.

As shown in FIG. 4J, the process 400 may include forming the conductive layer 275 (e.g., cell contact structures) within the cavities 420. The conductive layer 275 may comprise, consist of, or consist essentially of materials such as tungsten, aluminum, and titanium nitride, among other examples. In some implementations, a deposition tool may be used for deposition of the conductive layer 275 using a PVD technique, an atomic layer deposition (ALD) technique, a CVD technique, an electroplating technique, or other suitable deposition technique.

As indicated above, the process steps described in connection with FIGS. 4A through 4J are provided as examples. Other examples may differ from what is described with respect to FIGS. 4A through 4J.

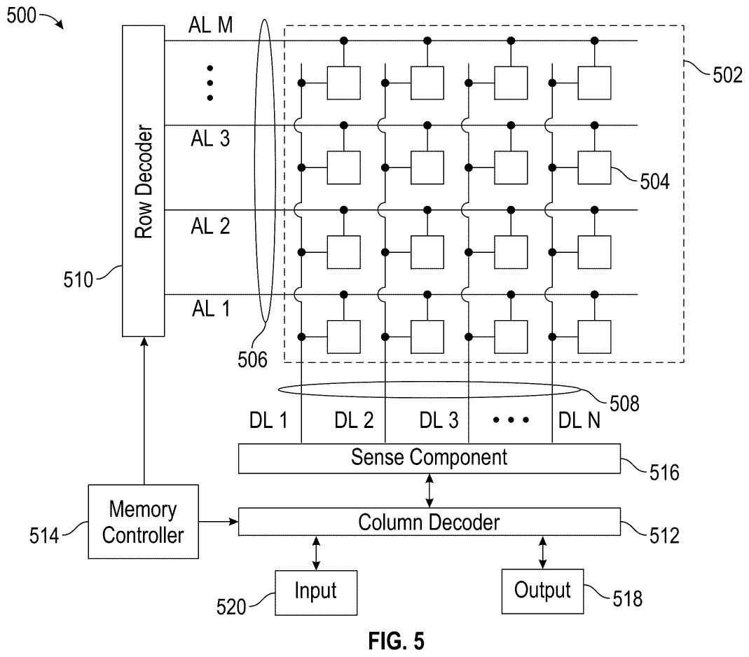

FIG. 5 is a diagrammatic view of an example memory device 500 described herein. The memory device 500 may include a memory array 502 that includes multiple memory cells 504. A memory cell 504 is programmable or configurable into a data state of multiple data states (e.g., two or more data states). For example, a memory cell 504 may be set to a particular data state at a particular time, and the memory cell 504 may be set to another data state at another time. A data state may correspond to a value stored by the memory cell 504. The value may be a binary value, such as a binary 0 or a binary 1, or may be a fractional value, such as 0.5, 1.5, or the like. A memory cell 504 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 504 by activating or selecting the appropriate access line 506 (shown as access lines AL 1 through AL M) and digit line 508 (shown as digit lines DL 1 through DL N). An access line 506 may also be referred to as a “row line” or a “word line,” and a digit line 508 may also be referred to a “column line” or a “bit line.” Activating or selecting an access line 506 or a digit line 508 may include applying a voltage to the respective line. An access line 506 and/or a digit line 508 may comprise, consist of, or consist essentially of a conductive material, such as a metal (e.g., copper, aluminum, gold, titanium, or tungsten) and/or a metal alloy, among other examples. In FIG. 5, each row of memory cells 504 is connected to a single access line 506, and each column of memory cells 504 is connected to a single digit line 508. By activating one access line 506 and one digit line 508 (e.g., applying a voltage to the access line 506 and digit line 508), a single memory cell 504 may be accessed at (e.g., is accessible via) the intersection of the access line 506 and the digit line 508. The intersection of the access line 506 and the digit line 508 may be called an “address” of a memory cell 504.

In some implementations, the logic storing device of a memory cell 504, such as a capacitor, may be electrically isolated from a corresponding digit line 508 by a selection component, such as a transistor. The access line 506 may be connected to and may control the selection component. For example, the selection component may be a transistor, and the access line 506 may be connected to the gate of the transistor. Activating the access line 506 results in an electrical connection or closed circuit between the capacitor of a memory cell 504 and a corresponding digit line 508. The digit line 508 may then be accessed (e.g., is accessible) to either read from or write to the memory cell 504.

A row decoder 510 and a column decoder 512 may control access to memory cells 504. For example, the row decoder 510 may receive a row address from a memory controller 514 and may activate the appropriate access line 506 based on the received row address. Similarly, the column decoder 512 may receive a column address from the memory controller 514 and may activate the appropriate digit line 508 based on the column address.

Upon accessing a memory cell 504, the memory cell 504 may be read (e.g., sensed) by a sense component 516 to determine the stored data state of the memory cell 504. For example, after accessing the memory cell 504, the capacitor of the memory cell 504 may discharge onto its corresponding digit line 508. Discharging the capacitor may be based on biasing, or applying a voltage, to the capacitor. The discharging may induce a change in the voltage of the digit line 508, which the sense component 516 may compare to a reference voltage (not shown) to determine the stored data state of the memory cell 504. For example, if the digit line 508 has a higher voltage than the reference voltage, then the sense component 516 may determine that the stored data state of the memory cell 504 corresponds to a first value, such as a binary 1. Conversely, if the digit line 508 has a lower voltage than the reference voltage, then the sense component 516 may determine that the stored data state of the memory cell 504 corresponds to a second value, such as a binary 0. The detected data state of the memory cell 504 may then be output (e.g., via the column decoder 512) to an output component 518 (e.g., a data buffer). A memory cell 504 may be written (e.g., set) by activating the appropriate access line 506 and digit line 508. The column decoder 512 may receive data, such as input from input component 520, to be written to one or more memory cells 504. A memory cell 504 may be written by applying a voltage across the capacitor of the memory cell 504.

The memory controller 514 may control the operation (e.g., read, write, re-write, refresh, and/or recovery) of the memory cells 504 via the row decoder 510, the column decoder 512, and/or the sense component 516. The memory controller 514 may generate row address signals and column address signals to activate the desired access line 506 and digit line 508. The memory controller 514 may also generate and control various voltages used during the operation of the memory array 502.

In some implementations, the memory device 500 includes the multi-layer pad structure 245 and/or an integrated assembly that includes the multi-layer pad structure 245. For example, the memory array 502 may include the multi-layer pad structure 245 and/or an integrated assembly that includes the multi-layer pad structure 245. Additionally, or alternatively, the memory cell 504 may include a memory cell described elsewhere herein.

As indicated above, FIG. 5 is provided as an example. Other examples may differ from what is described with respect to FIG. 5.

In some implementations, an integrated assembly includes a semiconductor device structure, comprising: a first semiconductive layer; and a multi-layer pad structure over the first semiconductive layer and extending laterally beyond the first semiconductive layer, comprising: a second semiconductive layer having at least a portion that is directly on and conjoined with the first semiconductive layer; a compound layer that is directly on and conjoined with the second semiconductive layer, comprising: a base material of the second semiconductive layer combined with a metal element; and a conductive layer stack that is directly on and conjoined with the compound layer.

In some implementations, an apparatus includes a capacitive structure; a cell contact structure comprising a single conductive layer and electrically coupled with the capacitive structure; an active area; a shallow trench isolation region that is proximate to the active area; and a cell contact pad structure that is between the cell contact structure and the active area and that overlaps at least a portion of the shallow trench isolation region, comprising: a semiconductive layer having at least a portion directly on and conjoined with the active area; a silicide layer having at least a portion directly on and conjoined with the semiconductive layer; and a metallization stack directly on and conjoined with the silicide layer.

In some implementations, a method includes receiving a semiconductor device structure with an active area derived from a polysilicon layer; forming a cell contact pad structure that includes a semiconductive layer having a portion that is directly on and conjoined with the active area, a silicide layer that is directly on and conjoined with the semiconductive layer, and a metallization stack that is directly on and conjoined with the silicide layer, wherein the cell contact pad structure is substantially void-free; and forming a cell contact structure that is directly on and conjoined with the cell contact pad structure.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a semiconductor device structure, comprising:
a first semiconductive layer; and
a multi-layer pad structure over the first semiconductive layer and extending laterally beyond the first semiconductive layer, comprising:
a second semiconductive layer having at least a portion that is directly on and conjoined with the first semiconductive layer;
a compound layer that is directly on and conjoined with the second semiconductive layer, comprising:
a base material of the second semiconductive layer combined with a metal element; and
a conductive layer stack that is directly on and conjoined with the compound layer.

2. The integrated assembly of claim 1, wherein the first semiconductive layer and the second semiconductive layer comprise:
a same material selected from the group consisting of:
polysilicon,
gallium arsenide,
indium phosphide, and
gallium nitride.

3. The integrated assembly of claim 1, wherein the first semiconductive layer and the second semiconductive layer comprise:
different materials selected from the group consisting of:
polysilicon,
gallium arsenide,
indium phosphide, and
gallium nitride.

4. The integrated assembly of claim 1, wherein the compound layer comprises a material selected from the group consisting of:
cobalt silicide,
titanium silicide, and
nickel silicide.

5. The integrated assembly of claim 1, wherein the conductive layer stack comprises:
a single conductive layer,
wherein the single conductive layer is directly on and conjoined with the compound layer.

6. The integrated assembly of claim 1, wherein the conductive layer stack comprises:
a lower, conductive layer that is directly on and conjoined with the compound layer, and one or more conductive layers over the lower, conductive layer.

7. The integrated assembly of claim 6, wherein at least one layer of the conductive layer stack comprises a material selected from the group consisting of:
tungsten,
aluminum, and
titanium nitride.

8. An apparatus, comprising:
a capacitive structure;
a cell contact structure comprising a single conductive layer and electrically coupled with the capacitive structure;
an active area;
a shallow trench isolation region that is proximate to the active area; and
a cell contact pad structure that is between the cell contact structure and the active area and that overlaps at least a portion of the shallow trench isolation region, comprising:
an epitaxial layer having at least a portion directly on and conjoined with the active area;
a silicide layer having at least a portion directly on and conjoined with the epitaxial layer; and
a metallization stack directly on and conjoined with the silicide layer.

9. The apparatus of claim 8, wherein the cell contact structure is directly on and conjoined with an upper layer of the metallization stack.

10. The apparatus of claim 8, wherein a thickness of the epitaxial layer is less than approximately 20 nanometers.

11. The apparatus of claim 8, wherein a ratio of a width of the cell contact pad structure to a thickness of the cell contact pad structure is less than approximately 3:2.

12. A method, comprising:
receiving a semiconductor device structure with an active area derived from a polysilicon layer;
forming a cell contact pad structure that includes a semiconductive layer having a portion that is directly on and conjoined with the active area, a silicide layer that is directly on and conjoined with the semiconductive layer, and a metallization stack that is directly on and conjoined with the silicide layer,
wherein the cell contact pad structure is substantially void-free; and
forming a cell contact structure that is directly on and conjoined with the cell contact pad structure.

13. The method of claim 12, wherein forming the cell contact pad structure includes:
forming the semiconductive layer using an epitaxial growth operation.

14. The method of claim 12, further comprising:
exposing the semiconductive device structure to an annealing operation,
wherein a thermal budget of the silicide layer satisfies a temperature threshold associated with the annealing operation.

15. The method of claim 12, wherein forming the cell contact pad structure includes:
forming a cavity that removes portions of the active area and a dielectric layer adjacent to the active area, and
forming the cell contact pad structure in the cavity.

16. The method of claim 12, wherein forming the cell contact pad structure includes:
forming the cell contact pad structure using a hard mask pattern to mask a bit line contact structure during formation of at least a portion of the cell contact pad structure.

17. The method of claim 12, wherein forming the cell contact pad structure includes:
depositing the metallization stack directly on the silicide layer, and
planarizing the metallization stack.

18. The method of claim 12, wherein forming the cell contact pad structure includes:
forming the metallization stack from a single metallization layer.

19. The method of claim 12, wherein forming the cell contact pad structure includes:
forming the metallization stack from at least two metallization layers.

20. The method of claim 12, wherein forming the cell contact structure includes:
forming the cell contact structure using a selective deposition process that forms the cell contact structure from a single conductive layer.
